(19) United States
(12) Patent Application Publication
(10) Pub. No.: US 2018/0113510 A1
(43) Pub. Date: Apr. 26, 2018

(54) DISPLAY DEVICE HAVING A TOUCH-SENSITIVE DISPLAY UNIT

(71) Applicant: Preh Car Connect GmbH, Dresden (DE)

(72) Inventor: Rochus Werner JENTSCH, Dresden (DE)

(73) Assignee: Preh Car Connect GmbH, Dresden (DE)

(21) Appl. No.: 15/784,894

(22) Filed: Oct. 16, 2017

(30) Foreign Application Priority Data
Oct. 24, 2016 (DE) 10 2016 220 858.6

(51) Int. Cl. G06F 3/01; G06F 3/041

(52) U.S. Cl. CPC G06F 3/016; G02F 1/133305; G06F 3/0412

(57) ABSTRACT

The present disclosure relates to a display device having a base element and a display unit arranged in front of the base element, the display unit being divided into a plurality of display segments. Several of the display segments comprise a respective touch-sensitive display element and an actuator element. The display element is designed to deflect the display element in relation to the base element, if a user touches the display element.

This application claims priority to the German Application No. 10 2016 220 858.6, filed Oct. 24, 2016, now pending, the contents of which are hereby incorporated by reference.

The present disclosure relates to a display device having a touch-sensitive display unit; and a process for operating the display device.

By a touch-sensitive display unit an input and output unit is understood, from which information may visually be output, and by touching of which inputs into an electronic device may be performed. For example, a so-called touchscreen is such a touch-sensitive display unit.

A conventional display device having a touch-sensitive display unit allows a user to perform an input by touching the display unit, without using another input unit, such as for example a separate keyboard or a computer mouse. Thus, the display device is user-friendly and space saving. However, the user solely receives a visual feedback as an input confirmation, the user being required to watch the display unit. However, in some applications such a visual input check is onerous, undesirable or even dangerous.

In a case where the display device is being used in a vehicle (for example as part of a navigation device, an infotainment device or a radio navigation device), the driver is required to look at the display unit in order to visually verify if touching the display unit causes an input. By this, the driver might become distracted from watching the ongoing traffic. Hence, some display devices that have a touch-sensitive display unit are provided with a haptic feedback function, by which a haptic feedback may be imparted to a user while touching the display unit by a movement of the display unit.

The object of the present disclosure is to provide a display device comprising a touch-sensitive display unit having an improved haptic feedback function.

According to the present disclosure, the object will be solved by the characteristics of claim 1.

Different embodiments of the present disclosure are the object of subclaims.

A display device according to the present disclosure comprises a base element and a display unit arranged in front of the base element, the display unit being divided into a plurality of display segments. Several among the display segments each have a touch-sensitive display element and an actuator element, the actuator element being configured to deflect the display element in relation to the base element, when a user touches the display element.

The display device allows giving a haptic feedback to a user upon his touch of the display unit by deflecting a display element of a display segment of the display unit being by way of the actuator element of this display segment while touching the display element or following touch of the display element. By this, it may for example be signaled to the user that a touch of the display element results in an input. Consequently, there is no need for the user to look at the display unit to verify if the touch of the display unit actually results in an input. Such a haptic input confirmation improves ease of use of the display device and is especially advantageous if a visual input check is onerous, undesirable or dangerous, as in the example named above of a display device used in a vehicle.

Alternatively or in addition, it is possible that a display element will be deflected following touch of another display element. In other words, deflection of a display element is caused by the user touching another display element.

Dividing the display unit into several display segments, of which several display segments comprise a respective touch-sensitive display element and an actuator element for deflecting the display element, allows for creating a haptic feedback that is locally focused to an area of the display unit touched by the user of the display device. For this, for example only one single actuator element or only few actuator elements become activated. This allows the haptic feedback to be assigned to the touched area in a locally dissolved manner.

Another advantage of this division of the display unit resides in that, for generating a haptic feedback to a touch of the display unit by a user of the display device, there is no need to deflect the entire display unit, but the deflection may be focused to a locally limited area of the display unit, in which the touch id performed. For this purpose, only the touched display element as well as further display elements in the vicinity thereof are optionally deflected. Thus, the mass to be deflected to generate a haptic feedback will advantageously be reduced compared to a deflection of the entire display unit. Due to this, energy consumption and reaction time to generate the haptic feedback may be reduced. Furthermore, the actuator elements may be dimensioned comparatively simple and small.

An embodiment of the present disclosure provides several of the display elements to be movably connected directly to an adjacent one of the respective display elements. In this context, for example one of the display elements, with each one being movably connected directly to an adjacent one of the display elements, has a deformable area enabling the movement.

The movable direct connection of adjacent display elements allows the deflection of one of these display elements in relation to an adjacent display element. The deformable area of one of these display elements allows deflection in a simple manner.

Another embodiment of the present disclosure provides for user interfaces facing away from the base element of two display elements adjacent to each other form an almost planar continuous first surface and back sides facing the base element of two display elements form a continuous second surface, which has an oblong recess that extends along a boundary between the two display elements.

The described design of the user interfaces of two display elements adjacent to each other as an almost planar continuous surface advantageously prevents discontinuities or interruptions of the surface from favoring any contamination, impeding touch by a user or confusing the user in touching the surface. The oblong recess between the backsides of the two display element adjacent to each other allows flexible coupling of the display elements, so that the display elements are deflectable relative to each other.

Another embodiment of the present disclosure provides for the actuator elements to be able of being concurrently activated, several of the actuator elements to be able of being concurrently activated and/or one of the actuator elements to be able of being activated independently from the other actuator elements.

The capacity of simultaneous activation of all or several actuator elements and the capacity of activation of individual actuator elements independently from each other advantageously allows generation of different types of haptic feedbacks by way of simultaneous or successive activation of actuator elements (the cooperation thereof, respectively). In this way, especially discriminated haptic information may be delivered to a user. For example, different inputs that are done by touches of the display unit may result in different types of haptic feedbacks. In this way, it may be signaled to the user upon touching the display unit, which input causes a specified touch of the display unit. For this purpose, for example, a specific haptic feedback is created by activating several actuator elements in a specified order.

For example, a haptic response to a movement along the surface of the display unit of a user's finger touching the display unit may be the generation of a haptic feedback accompanying the movement. For this purpose, actuator elements will successively be activated along a trajectory of this movement. This is especially advantageous for applications, where inputs may be done by such movements (gestures).

Another embodiment of the present disclosure provides for the actuator element of one of the display segments being attached to the base element. In this case, the display element of the display segment may firmly be connected to the actuator element, may be coupled to the actuator element in a loosely fitting manner or may resiliently be coupled to the actuator element.

Attachment of the actuator element to the base element has the advantage of being a true counter acting force, acting on the actuator element from the base element, when the actuator element, upon its extension, presses against the display element. The loose fit of the display elements to the actuator element and the resilient coupling of the display element to the actuator element facilitate the deflection of the display element by an actuator element of an adjacent display segment, the display element of which is connected to the display element. The resilient coupling supports return of the display element into its initial position following deflection and facilitates generation von vibrations of the display element by reset forces that counteract the deflection.

Another embodiment of the present disclosure provides for one of the display elements comprising a light-transmissive area and a backlighting element attached to the base element is associated to the display element, the backlighting element being designed to irradiate through the light-transmissive area. In this context, for example a light protection element is associated to the display element, which is designed to shield a light protection space arranged between the base element and the display element in the backlighting element.

The backlighting element for example allows using a display element that comprises a liquid crystal display element. Attaching the backlighting element to the base element has the advantage that only the display element but not the backlighting element is required to be deflected in relation to the actuator element so that the mass required to be moved by the actuator element is reduced compared to a display device, in which both the display element and the backlighting element are deflected by the actuator element. In this way, the actuator element may easier be configured and the response characteristic of the display element to the actuator element may be improved. Furthermore, it will be avoided that the backlighting element becomes damaged by a deflection caused by the actuator element.

The light protection element, on the one hand, shields the light protection space from interfering light from the surroundings of the light protection space and, on the other hand, focuses light that is emitted by the backlighting element arranged in the light protection space onto the display element that is associated to the light protection element.

Another embodiment of the present disclosure provides for one of the display elements comprising a light emitting diode.

This allows realizing the display function of the display element by way of a light emitting diode that is incorporated into the display element. In this case, generally no backlighting element is required for the display element, since the display element may be self-luminous.

In a process according to the present disclosure, a display device according to the present disclosure is operated with the advantages mentioned above. A user touches one of the display elements so that the display element is being deflected by way of one of the actuator elements in relation to the base element.

For example, during operation of the display device each display segment that comprises an actuator element will be transferred to a feedback operation mode upon touching the display element of the display segment so that the display segment will be operated in the feedback operation mode. The feedback operation mode, for example, is activated by way of an application program that controls the display unit.

Alternatively or in addition, a display segment may be designed to create a standard deflection of its display element by itself by way of an actuator element. A standard deflection may be generated, if no application program controlling the feedback operation mode of the display unit is present. Thus, generation of a haptic feedback is permitted without any application program providing for or defining generation of a haptic feedback, respectively. Moreover, a consistent (to be used for different application programs), and thus easy to be memorized, deflection pattern may be provided to the user by way of the standard deflection. The standard deflection may furthermore be used for a certain brand-specific deflection pattern.

A possible standard deflection is a deflection of the display element almost perpendicular to its touch-sensitive user interface. This deflection may (in analogy to nodding) be combined with an affirmative input such as “Yes” or “OK”. Another possible standard deflection is a deflection of the display element almost parallel to its touch-sensitive user interface. This deflection may (in analogy to head-shaking) be combined with an input such as “No” or “cancel”.

Another embodiment of the process provides for a vibration of the display element being generated as a deflection of a display element, especially as a standard deflection, by way of an actuator element. A variation of this embodiment provides for a different vibration of a display element or multiple display elements are being associated to different inputs that are each performed by a touch of the display unit. The vibrations may differ from each other by their frequencies, amplitudes and/or durations. Moreover, the embodiment provides for, upon a touch of the display unit, vibration of the display unit being generated that is associated to the input performed by the touch. In this context, an input, for example by way of an application program controlling the display unit, a frequency, an amplitude and/or a duration will be associated to the vibration.

Further embodiments of the present disclosure will be explained in detail in the following,

wherein:

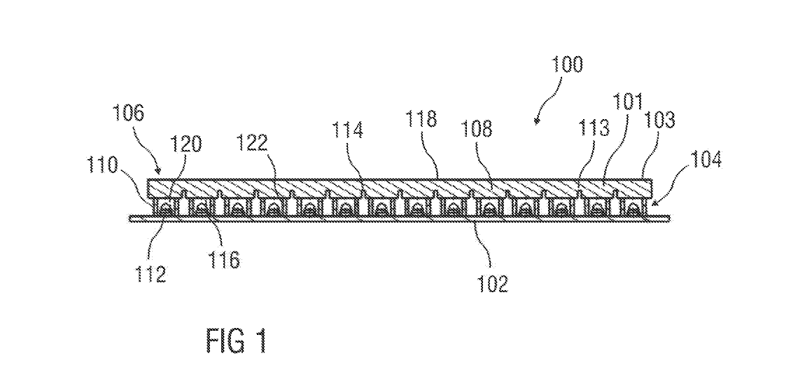

FIG. 1 is a sectional representation of a first embodiment of a display device according to the present disclosure,

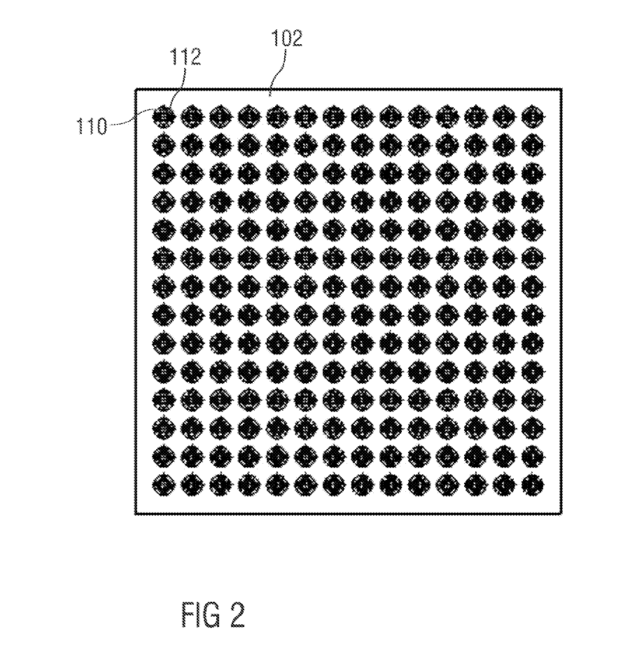

FIG. 2 is a top view of a base element and actuator elements attached thereto and backlighting elements of the display device shown in FIG. 1,

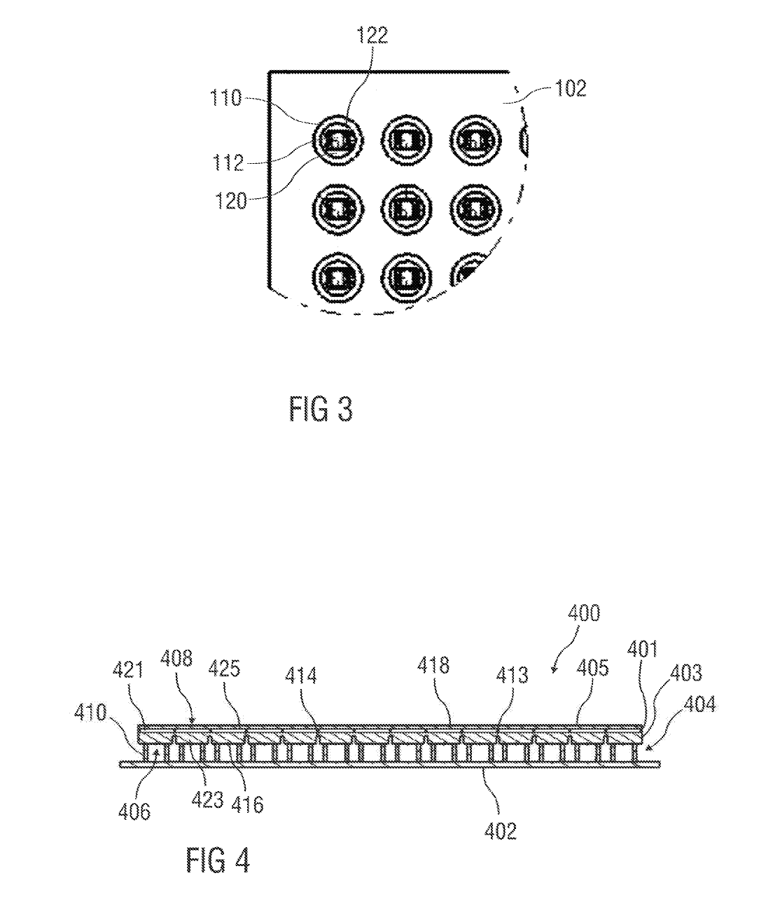

FIG. 3 is an enlarged section of the base element represented in FIG. 2,

FIG. 4 is a sectional representation of a second embodiment of a display device according to the present disclosure,

FIG. 5 is a sectional top view of a base element and actuator elements attached thereto of the display device shown in FIG. 4, and

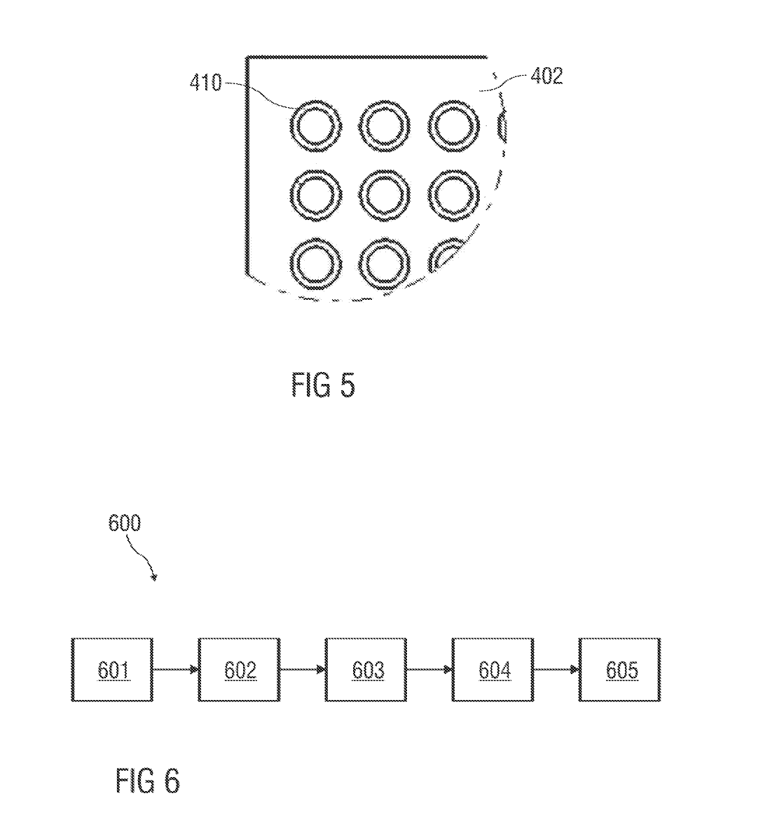

FIG. 6 is a flow chart of a process according to one embodiment of the present disclosure.

In the figures, equal parts are designated with equal reference numbers.

FIG. 1 shows a sectional representation of a first embodiment of a display device 100 according to the present disclosure. The display device 100 comprises a base element 102 and a display unit 104.

The display unit 104 is divided into several display segments 106. Each display segment 106 comprises a display element 108, an actuator element 110 and a backlighting element 112.

Each display element 108 comprises a translucent area, wherein a light transmittance of the area is adjustable. Display elements 108 adjacent to each other movably attached directly to each other by the provision of a deformable area 113 between them that allows the movement. For example, such an area is formed resiliently. In this way, the display elements 108 of the display unit 104 form a deformable display screen 101, for example a deformable liquid crystal screen (LCD=Liquid Crystal Display).

Each display element 108 comprises a front-side user interface 118 facing away from the base element 102. The user interfaces 118 of two display elements 108 adjacent to each other form an almost planar continuous first surface. The user interfaces 118 of the display elements 108 of the display unit 104 form an almost planar continuous display screen surface 103 of the display screen 101 or of the display unit 104, respectively.

Moreover, each display element 108 comprises a backside 116 facing the base element 102. The backsides 116 of two adjacent display elements 108 form a continuous second surface, which comprises an oblong recess 114. The recess extends along a border between the two display elements 108 and may be of a groove-like shape. The recesses 114 between the back sides 116 of the display elements 108 of the display unit 104 form a lattice structure, lattice cells of which are formed by the back sides 116 of the display elements 108. The lattice structure improves the movability of the display elements 108 to each other, thereby improving deformability of the display screen 101.

Moreover, each display element 108 is formed in a touch-sensitive manner so that a touch of the display screen surface 103 performed by a user of the display device 100 may be detected. In this way, a user of the display device 100 may perform an input by touching the display unit 104. Such an input is, for example, a confirmation of an input request or more complex input by using an operation panel represented by a display unit 104, for example a keyboard.

The base element 102 is arranged behind the display unit 104 and is provided as a support for the actuator elements 110 and several backlighting elements 112. The base element 102 is for example formed as a circuit board, as a housing part of a device or as an area of a center console of a vehicle.

The actuator element 110 of a display segment 106 connects the display element 108 of the display segment 106 to the base element 102 and is designed to deflect the display element 108 in relation to the base element 102, if a user of the display device 100 touches the display element 108. Alternatively, it is possible, that an actuator element, on the one hand, may be connected to a display element, but on the other hand, is not connected to the base element.

The actuator element 110 may be designed to create deflections of the display element 108 solely in one deflection direction or may be designed to create deflections in different deflection directions. A possible deflection direction extends almost perpendicular to the user interface 118 of the display element 108 or the display screen surface 103, respectively. Other possible deflection directions extend almost parallel to the user interface 118 of the display element 108 or to the display screen surface 103, respectively. The actuator element 110 may be controlled by a calculating unit (not represented), by which an application program is executed.

The actuator elements 110 are attached to the base element 102, each one extending from the base element 102 to a display element 108. The actuator element 110 of a display segment 106 may fixedly be connected to the display element 108 of the display segment 106. Alternatively, the display elements 108 are loosely fitted to the actuator elements 110, so that the display screen 101 is “floatingly” supported on the actuator elements 110. As another alternative, the display element 108 is resiliently connected to the actuator element 110.

The actuator elements 110 may be enabled individually, independently from each other. Alternatively, several of the actuator elements 110, for example a group of actuator elements 110, may solely be enabled together. As another alternative, all actuator elements 110 of the display device 100 may solely be enabled together.

The actuator element 110 of a display segment 106 may deflect the display element 108 of the display segment 106 by changing a deflection of the actuator element 110. The deflection is done in the direction extending almost perpendicular to the user interface 118 of the display element 108 or the display screen surface 103, respectively. Alternatively, or in addition, the display element 108 may be deflected in a direction extending almost parallel to the user interface 118 of the display element 108 or the display screen surface 103, respectively. Optionally, the display element may be deflected in multiple directions, which each are parallel or oblique to the user interface 118 of the display element 108 or display screen surface 103, respectively.

For deflecting the display element 108, a deflection amount or a dimension (for example a height or a length) of the actuator element 110 is changed by appx. 0.1 mm to appx. 0.5 mm. The deflection is significantly perceptible by a user of the display device 100, who touches the display element 108 and may be generated in relatively simple manner. For this purpose, the actuator element 110 for example comprises an electromagnetic actuator, a piezoelectric actuator, a magnetostrictive actuator, a pneumatic actuator, a hydraulic actuator or an electromechanical actuator auf.

The backlighting element 112 of a display segment 106 is designed to irradiate through the display element 108 of the display segments 106 and is therefore attached behind the display element 108 to the base element 102. For example, the backlighting element 112 comprises a light emitting diode or several light emitting diodes for irradiating through the display element 108. Especially, the backlighting element may be an organic light emitting diode or may be multiple organic light emitting diodes for irradiating through the display element.

In addition to FIG. 1, reference is made to the FIGS. 2 and 3 in the following. FIG. 2 shows a top view of the base element 102 and the actuator elements 110 attached thereto and backlighting elements 112 of the display device 100 shown in FIG. 1. FIG. 3 shows an enlarged section of the base elements 102 and the actuator elements 110 attached thereto and backlighting elements 112.

The display segments 106 are arranged like a matrix, i.e. they are arranged in multiple lines and rows each containing display segments 106 arranged along a line.

The actuator element 110 of each display segment 106 is configured in the form of a hollow cylinder surrounding a light protection space 120 arranged between the base element 102 and the display element 108 of the display segment 106, wherein the backlighting element 112 is arranged in the light protection space 120. Alternatively, the actuator element may differently be configured, for example cuboidal or rod-shaped.

Moreover, each display segment 106 comprises a light protection element 122 to shield light protection space 120. The light protection element 122, on the one hand, shields the light protection space 120 against interfering light from the surroundings of the light protection space 120 and, on the other hand, focuses light emitted from the backlighting element 112 arranged in the light protection space 120 to the display element 108 arranged above the backlighting element 112.

In the display device 100 represented in den FIGS. 1 to 3, the light protection element 122 is formed by an internal surface of the actuator element 110 that surrounds the light protection space 120 and that is configured imperviously to light. Alternatively, the light protection element may also be formed by an external surface of the actuator element, or may be formed as a separate tube-shaped component surrounding the light protection space.

If the light protection element 122 of a display segment 106 is configured as a separate component, the light protection element 122 may integrally be configured or may be configured in two parts. In an integral configuration, the light protection element 122 is for example attached to the base element 102 via a first end surrounding the backlighting element 112 and is attached to the backside 116 of the display element 108 of the display segment 106 via a second end. In this context, the light protection element 122 is deformably formed to allow movements of the display element 108 in relation to the base element 102.

In a two-part configuration, the light protection element 122 comprises two protection elements separated from each other which each are in the form of a hollow cylinder, the protection elements each surrounding part of the light protection space 120. In this context, a first one of the two protection elements surrounds the backlighting element 112 and is attached to the base element 102. The second one of the two protection elements is attached to the display element 108 of the display segment 106 and extends to the first protection element. Optionally, the two protection elements overlap to allow movement of the display element 108 in relation to the base element 102.

FIG. 4 shows a sectional representation of a second embodiment of a display device 400 according to the present disclosure. The display device 400 comprises a base element 402 and a display unit 404.

The display unit 404 is divided into several display segments 406. Each display segment 406 comprises a display element 408 and an actuator element 410.

Each display element 408 comprises a light emitting diode unit 421, a support segment 423 and a protective layer segment 425. Each one of the light emitting diode units 421 has one or more light emitting diodes, together forming a light emitting diode display screen 401. Thus, the light emitting diode are not used for backlighting, but for generating an image. For this purpose, the light emitting diode of the light emitting diode units 421 are able to be electronically actuated independently from each other. The light emitting diode of the light emitting diode units 421 are for example inorganic or organic light emitting diodes. Display elements 408 that are adjacent to each other are movably attached directly to each other, showing an deformable area 413 that allows the movement and, for example, is resiliently configured.

The light emitting diode unit 421 of a display segment 406 is arranged on a front side of the support segment 423 of the display segment 406. The support segments 423 belong to a deformable light emitting diode support 403 of the light emitting diode units 421. For example, the light emitting diode support 403 is formed as a deformable plastics support.

Each display element 408 comprises a front-side user interface 418 facing away from the base element 402 and a backside 416 facing the base element 402. The user interface 418 is a surface of the protective layer segment 425 of the display element 408. The backside 416 is a surface of the support segment 423 of the display element 408. The user interfaces 418 of two display elements 408 adjacent to each other form an almost planar continuous first surface. The backsides 416 of two display elements 408 adjacent to each other form a continuous second surface.

On the backside the light emitting diode support 403 comprises groove-shaped oblong recesses 414, forming a lattice structure and each extending between the back sides 416 of the support segments 423 of two display elements 408 adjacent to each other. In other words, the backsides 416 of two display elements 408 adjacent to each other form a continuous second surface, which comprises one of the oblong recesses 414. The lattice cells of the lattice structure formed by the recesses 414 of the light emitting diode support 403 are thus formed by the backsides 416 of the support segments 423. In this way, the movability of the support segments 423 relative to each other and the deformability of the light emitting diode support 403 will be increased.

The protective layer segment 425 of a display segment 406 is arranged on a front side of the light emitting diode unit 421 of the display segment 406. The protective layer segments 425 of the display segments 406 of the display device 400 form a protective layer 405 for the protection of the light emitting diode units 421 against interfering influences such as humidity, contaminants, dust, gas and/or mechanical actions. The protective layer 405 is transparently configured for light generated by the light emitting diode units 421. Moreover, the protective layer 405 is deformably configured.

Thus, the display unit 404 comprises a light emitting diode display screen 401 formed by the light emitting diode units 421 which is arranged between der protective layer 405 having the protective layer segments 425 and the light emitting diode support 403 having the support segments 423. Due to the deformability of the deformable areas 413 of the light emitting diode units 421, the protective layer 405 and of the light emitting diode support 403, the display unit 404 is as well deformable.

Moreover, each display element 408 is formed in a touch-sensitive manner, wherein touches of a front-side user interface 418 of the display element 408 performed by a user of the display device 400 are detectable. The touch-sensitive user interfaces 418 of the display elements 408 allow inputs to be performed by a user of the display device 400 by touching the user interfaces 418. Such inputs are, for example, a confirmation of an input request or a more complex input by using an operating panel represented by the display unit 404, for example a keyboard.

The base element 402 is arranged behind the display unit 404 and is formed as a support for the actuator elements 410.

The actuator element 410 of a display segment 406 connects the display element 408 of the display segment 406 to the base element 402 and is designed to deflect the display element 408 in relation to the base element 402, when a user of the display device 400 touches the display element 408. The actuator elements 410 are attached to the base element 402, each one extending from the base element 402 to a display element 408. The actuator element 410 of a display segment 406 is not rigidly connected to the display element 408 of the display segment 406, but the display element 408 is, for example, loosely supported at the actuator element 410 so that the display unit 404 is “floatingly” supported on the actuator element 410. Alternatively, the display element 408 is resiliently connected to the actuator element 410.

The actuator element 410 of a display segment 406 may deflect the display element 408 of the display segment 406 by changing a deflection of the actuator element 410 towards a direction almost perpendicular to the user interface 418 of the display element 408 and/or towards one or more directions almost parallel to the user interface 418 of the display element 408. For this purpose, a deflection of the actuator element 410 is changed by appx. 0.1 mm to appx. 0.5 mm. Such a change of deflection generates a deflection of the display element 408 coupled at the actuator element 410, the deflection being significantly perceptible by a user of the display device 400 touching the display element 408 and may be generated in a relatively simple manner. The actuator element 410 for example comprises an electromagnetic actuator, a piezoelectric actuator, a magnetostrictive actuator, a pneumatic actuator, a hydraulic actuator or an electromechanical actuator. The actuator elements 410 of the display device 400 are able to be individually activated, independently from each other or are able to be activated in groups.

In the following, reference is made to FIG. 5, in addition to FIG. 4. FIG. 5 shows a sectional top view of the base elements 402 and actuator elements 410 attached thereto.

The actuator element 410 of each display segment 406 is configured in the form of a hollow cylinder.

The display segments 406 are arranged in a matrix-like manner, i.e. the display segments 406 forming parallel lines and columns perpendicular thereto, each containing display segments 406 arranged in one line.

The display devices 100, 400 represented in den FIGS. 1 to 5 may be configured in various ways and may be modified. For example, each display segment 106, 406 may be associated to exactly one image point (Pixel) to be displayed by the display unit 104, 404, i.e. each display element 108, 408 is designed to represent exactly one pixel. Alternatively, a display segment 106, 406 may also be associated to several pixels, which are represented by the display element 108, 408 of the display segment 106, 406.

Moreover, the lattice structure formed by the recesses 114, 414 may be configured in various ways. In the display devices 100, 400 represented in den FIGS. 1 to 5, each lattice cell of this lattice structure is associated to exactly one display segment 106, 406, i.e. a recess 114, 414 extends between the backsides 116, 416 of two adjacent display elements 108, 408. The lattice structure may even be formed in a rather coarse-grained manner, so that several display segments 106, 406 and especially several actuator elements 110, 410 are associated to one lattice cell.

Moreover, the lattice structure formed by the recesses 114, 414 may form a regular lattice, for example, a lattice having polygonal lattice cells, but the lattice structure may as well be formed irregularly, varying in size and/or shape of the lattice cells.

In addition, the display segments 106, 406 and/or the actuator elements 110, 410 may irregularly be arranged. Especially, the actuator elements 110, 410, unlike the embodiments of the present disclosure represented in the FIGS. 1 to 5, may irregularly be arranged at the base element 102, 402n, so that the distance of elements 110, 410 adjacent to each other will vary. Furthermore, the number and/or the position of the display segments 106, 406 that are associated to a lattice cell of the lattice structure formed by the recesses 114, 414 may vary.

Moreover, the actuator elements 110, 410 may be formed differently from the embodiments of the present disclosure represented in FIGS. 1 to 5, wherein they are configured in a hollow cylindrical manner having circular base areas. For example, the actuator elements 110, 410 could be configured in a hollow cylindrical manner having oval or polygonal base areas or could be configured full-cylindrically, for example in a rod-shaped manner.

The display devices 100, 400 represented in FIGS. 1 to 5 and the embodiments thereof and variants thereof, each allow a haptic feed back to the user's touch of the touch-sensitive display unit 104, 404 to be given to a user of the display device 100, 400 by deflecting the display element 108, 408 of a display segment 106, 406 of the display unit 104, 404 by the actuator element 110, 410 of this display segment 106, 406 upon touching the display element 108, 408. In this way, it may signaled to the user, by way of deflecting the display element 108, 408, for example, that touching the display element 108, 408 causes an input. Especially, the user, upon a haptic feedback to an input, is not required to look at the display unit 104, 404, in order to verify if the touch of the display unit 104, 404 in fact results in a (desired) input.

Division of the display unit 104, 404 into several display segments 106, 406 and ability of being activated independently from each other of the actuator elements 110, 410 allows a haptic feedback to be generated, that is locally focused to an area of the display unit 104, 404 touched by a user of the display device 100, 400, for example by solely activating one single actuator element 110, 410 or few actuator elements 110, 410 adjacent to each other. This allows the haptic feedback to be associated in a locally resolved manner to the respective area of the display unit 104, 404 that has been touched. Especially, the mass to be generated for the generation of a haptic feedback will advantageously be reduced in comparison to a deflection of the complete display unit 104, 404. Thus, energy consumption and reaction time to generate the haptic feedback may be reduced. Furthermore, the actuator elements 110, 410 may be dimensioned in a comparatively simple and clear manner, thereby allowing reduction of the construction height of the display device 100, 400.

Deflection of solely locally limited areas of the display unit 104, 404 instead of the entire display unit 104, 404 for the generation of a haptic signal has the further advantage, that the display unit 104, 404 may be incorporated in a rather simple manner into a device that comprises the display unit 104, 404 as a component, since no movable support of the entire display unit 104, 404 is required.

The deformable areas 113, 413 of the display elements 108, 408 allow movable connections of the display elements 108, 408 to each other. Due to this, display elements 108, 408 that are adjacent to each other, are only loosely attached to each other so that deflection of a display element 108, 408 drags along adjacent display elements 108, 408 only to a very minor extend. In this way, activation of a single actuator element 110, 410 solely results in a locally limited deflection of the user interface 418 of the display unit 104, 404 and accordingly, the mass being moved by the actuator element 110, 410 is low.

On the other hand, coupling of display elements 108, 408 that are adjacent to each other, results in that by activation of an actuator elements 110, 410 not only a display element 108, 408 is deflected that is directly coupled to this actuator element 110, 410, but also adjacent display elements 108, 408 may be moved concurrently. In this way, multiple actuator elements 110, 410 may cooperate, wherein the type of haptic feedback generated thereby depends of the number and position of the activated actuator elements 110, 410.

This allows haptic feedbacks of different types to be generated by way of simultaneous activation of a different number and/or a different position of the actuator elements 110, 410. In this way, various information may be conferred to a user by way of haptic feedbacks. For example, different inputs may be performed by touching the display unit 104, 404, various haptic feedbacks, for example as input confirmations, may be associated. In this way, it may be signaled to the user, by touching the display unit 104, 404, which input causes the respective touch of the display unit 104, 404. For this purpose, the haptic feedback associated to that input is generated by the actuator elements 110, 410.

Moreover, haptic response can be made to a movement of a user's finger touching the display unit 104, 404, along the user interface 418 of the display unit 104. For this purpose, a haptic feedback accompanying the movement is generated by activating the actuator elements 110, 410 along a trajectory of this movement. This is especially advantageous for applications, wherein inputs may be performed by way of such movements (gestures).

In the display device 100 represented in den FIGS. 1 to 3, having a transparent display unit 104, the backlighting is realized by the use of backlighting elements 112 arranged on the base element 102, the backlighting elements 112 not being deflected by the actuator elements 110. In this way, the mass to be moved by each of the actuator elements 110 will advantageously be further reduced.

Whereas, in the display device 400 represented in den FIGS. 4 and 5 no backlighting is required, since the light emitting diode units 421 of the display unit 404 form a self-luminous light emitting diode display screen 401.

FIG. 6 shows a flow chart 600 of a process according to one embodiment of the present disclosure for operating a display device 100 represented in den FIGS. 1 to 3 or a display device 400 represented in the FIGS. 4 and 5.

In a first process step 601, visual information for a user of the display device 100, 400 is output by way of the display unit 104, 404 of the display device 100, 400, which provides an input in the form of a target-specific touch of one of the touch-sensitive display elements 108, 408 of the display unit 104, 404. Alternatively, by using an output unit (not represented) connected to the display device, acoustic information may be output to the user of the display device providing input by the user in the form of a target-specific touch of one of the touch-sensitive display elements of the display unit.

In a second process step 602, a touch-sensitive display element 108, 408 provided for the input is being touched by the user to perform an input. For this purpose, for example by using the display unit 104, 404, a respective operating panel is represented.

In a third process step 603, by way of the touched display element 108, 408, the touch, for example of the represented operating panel, is detected.

In a fourth process step 604, the display segment 106, 406 having the touched display element 108, 408, is transferred to a feedback operation mode, in order to generate a haptic feedback by way of its actuator element 110, 410. For example, the feedback operation mode will be activated by way of an application program that controls the display unit 104, 404. Moreover, the feedback operation mode may be activated by the display segment 106, 406 itself, which comprises the display element 108, 408 that has been touched, if no application program is present that controls the feedback operation mode of the display unit 104, 404, and the display segment 106, 406 is designed, by way of its actuator element 110, 410, to generate a standard deflection of its display element 108, 408 by itself.

In a fifth process step 605, the display element 108, 408 that has been touched will be deflected by the actuator element 110, 410 of the display segment 106, 406 comprising the display element 108, 408 that has been touched, according to the feedback operation mode. If the feedback operation mode is controlled by the application program, the actuator element 110, 410 is actuated by the application program. If no application program controlling the feedback operation mode of the display unit 104, 404 is present and the display segment 106, 406 is designed to generate a standard deflection of its display element 108, 408 by itself, by way of its actuator element 110, 410, standard deflection of the display element 108, 408 is generated.

A possible standard deflection is a deflection of the display element 108, 408 almost perpendicular to its touch-sensitive user interface 118, 418. This deflection may (in analogy to nodding) be combined with an affirmative input such as “Yes” or “OK.” Another possible standard deflection is a deflection of the display element 108, 408 almost parallel to its touch-sensitive user interface 118, 418. This deflection may (in analogy to head-shaking) be combined with an input such as “No” or “Cancel.”

Moreover, as a deflection of a display element 108, 408, especially as a standard deflection, a vibration of the display element 108, 408 may be generated for example by way of an actuator element 110, 410. In this context, it may especially be provided that different inputs, which each is performed by touching the display unit 104, 404, will each be associated to another vibration of one display elements 108, 408 or more display elements 108, 408. The vibrations may differ from each other by their frequencies, amplitude and/or durations. There will be generated that vibration of the display unit 104, 404 which may be associated to the input performed by the touch. In this context, a frequency, an amplitude and/or a duration of the vibration will be associated to an input, for example by way of an application program controlling the display unit.

1. A display device, comprising:
a base element and a display unit arranged in front of the base element, the display unit being divided into a plurality of display segments;
wherein several of the display segments each comprise a touch-sensitive display element and an actuator element, which is designed to deflect the display element in relation to the base element, if a user touches the display element.

2. The display device of claim 1, wherein several of the display elements are movably connected directly to a respective adjacent one of the display elements.

3. The display device of claim 2, wherein one of the display elements, which are movably connected directly to a respective adjacent one of the display elements, comprises a deformable area allowing the movement.

4. The display device of claim 1, wherein user interfaces facing away from the base element of two display elements adjacent to each other form an almost planar continuous first surface and the backsides facing the base element of the two display elements form a continuous second surface, which has an oblong recess extending along a border between the two display element.

5. The display device of claim 1, wherein the actuator elements are able to be activated together, several of the actuator elements are able to be activated together and/or one of the actuator elements is able to be activated independently of the other actuator elements.

6. The display device of claim 1, wherein the actuator element of one of the display segments is attached to the base element and the display element of the display segment is fixedly connected to the actuator element t, is loosely fitted to the actuator element or is resiliently coupled to the actuator element.

7. The display device of claim 1, wherein one of the display elements comprises a light-transmissive area and a backlighting element attached to base element is associated to the display element, the backlighting element being designed to irradiate through the light-transmissive area.

8. The display device according to claim 7, wherein a light protection element is associated to the display element having the light-transmissive area, the light protection element being designed to shield a light protection space arranged between the base element and the display element, wherein the backlighting element is arranged in the protection space.

9. The display device according to of claim 1, wherein one of the display elements comprises a light emitting diode.

10. A process for operating the display device of claim 1, wherein a user touches one of the display elements, so that the display element will be deflected by way of one of the actuator elements in relation to the base element.
